(19) United States
(12) Patent Application Publication
(10) Pub. No.: US 2025/0083629 A1
(43) Pub. Date: Mar. 13, 2025

(54) LOW-VOLTAGE ELECTRICAL SYSTEM WITH BATTERY PROTECTION UNDER HEAVY SYSTEM LOADS

(71) Applicant: Enterprise Electronics LLC, Madison Heights, MI (US)

(72) Inventors: Jeffrey Carl Vogel, Troy, MI (US); Oleksandr Dieiev, Farmington Hills, MI (US)

(73) Assignee: Enterprise Electronics LLC, Madison Heights, MI (US)

(21) Appl. No.: 18/883,488

(22) Filed: Sep. 12, 2024

Related U.S. Application Data
(60) Provisional application No. 63/582,055, filed on Sep. 12, 2023.

(51) Int. Cl. B60R 16/033; G01R 31/382; H02J 1/08

(52) U.S. Cl. CPC B60R 16/033; H02J 1/084; G01R 31/382

(57) ABSTRACT

A method for use aboard a host system having an electrical system includes measuring one or more electrical parameters of a battery of the electrical system, including a battery current and/or a battery voltage. The method includes estimating, via a controller as a switching condition, when a system load will cause a threshold excessive current inflow or outflow of the battery. In response to the switching condition, the method includes disconnecting the battery from the electrical system by opening a switch. An electrical system for a host system includes a switch disposed on a low-voltage power distribution bus, a battery that is selectively connectable to the bus via the switch, a sensor suite, and a controller configured to perform the method.

### CROSS-REFERENCE TO RELATED APPLICATIONS

The present application claims the benefit of priority to U.S. Provisional Application No. 63/582,055 filed on Sep. 12, 2023, which is hereby incorporated by reference in its entirety for all purposes.

### INTRODUCTION

The present disclosure relates to battery electric circuits for use aboard a host system, e.g., a motor vehicle having a gasoline-powered or diesel-powered internal combustion engine. Engine-driven passenger vehicles typically employ a low-voltage electrical system in which an alternator and a low-voltage battery, for instance a 12-15V lead-acid battery, act as respective energy-generating and energy-storing components. The battery in a low-voltage electrical system of an exemplary engine-driven motor vehicle typically outputs its peak battery current under two scenarios: (1) when cranking and starting the engine, and (2) when the alternator's current output is insufficient for maintaining a system-level voltage or bus voltage above the battery's voltage capability, such as when connecting high-load accessories to the battery. Both scenarios can shorten the battery's operating life.

### SUMMARY

Disclosed herein are electric circuit topologies and corresponding control strategies for switching an electrochemical battery into or out of a low-voltage electrical system during a high-load period. As contemplated herein, “high-load period” refers to a transient or sustained period during which excessive loads are placed on the battery and other components of the low-voltage electrical system. Such loads may include accessories such as winches or snowplow attachments, or perhaps other vehicle accessories in embodiments in which the low-voltage electrical system is used as part of a representative motor vehicle. The present solutions prevent load cycling-related damage to the battery by temporarily disconnecting the battery from the electrical system during the high-load period.

In accordance with one or more representative embodiments, a method for use aboard a host system having an electrical system includes measuring at least one electrical parameter on a power distribution bus via a sensor suite. The electrical parameter includes a current and/or a voltage on at least one node of the electrical system. The method further includes estimating, via a controller as a switching condition using the electrical parameter, when a system load on the electrical system will cause a threshold excessive current condition of the battery. In response to the switching condition, the method includes disconnecting the battery from the electrical system via the controller, in particular by opening a switch of the electrical system.

Measuring the electrical parameter(s) may include measuring the current via a current sensor as a battery current of the battery, and/or measuring the voltage via a voltage sensor as a battery voltage of the battery.

The electrical system in one or more implementations includes a capacitor that is connected to the power distribution bus. In such a case, the method may also include providing an available current source to the electrical system via the capacitor when the battery is disconnected from the electrical system.

Measuring the at least one electrical parameter may include measuring the current as a battery current of the battery. In such a case, the method may include determining a duration of a flow of the battery current into or out of the battery via a timer. In response to the duration, the method may also include opening the switch to disconnect the battery from the electrical system.

In one or more embodiments, the method may include determining when the switch has been in an open state for a predetermined period of time, and then closing the switch to reconnect the battery to the electrical system when the switch has been in the open state for the predetermined period of time.

The host system may be optionally constructed as a motor vehicle. The method in this instance may include determining if the motor vehicle is not running, and closing the switch when the motor vehicle is not running to connect the battery to the electrical system. The motor vehicle may include an engine connected to one or more road wheels. Determining if the motor vehicle is not running in this instance may include processing an engine speed signal via the controller. The system load may optionally include a winch or a snow plow attachment.

The electrical system described herein may include one or more comparator circuits. Estimating when the system load will cause the threshold excessive current of the battery may be performed by the controller using such comparator circuits.

An electrical system for a host system is also disclosed herein. The electrical system may include a switch disposed on a low-voltage power distribution bus, a battery that is selectively connectable to the low-voltage power distribution bus via the switch, a timer, a sensor suite having one or more sensors, a capacitor connected the low-voltage power distribution bus, and a controller in communication with the sensor suite. The controller is configured to determine an electrical parameter of the battery via the sensor suite, with the electrical parameter including at least one of a battery current or a battery voltage of the battery. The controller also estimates, as a switching condition using the electrical parameter and the timer, when a system load on the electrical system will cause a threshold excessive current outflow or inflow of the battery. In response to the switching condition, the controller disconnects the battery from the electrical system by opening the switch without disconnecting the capacitor from the low-voltage power distribution bus.

In yet another embodiment, an electrical system for a motor vehicle having an engine includes a switch disposed on the low-voltage power distribution bus, a battery that is selectively connectable to the low-voltage power distribution bus via the switch, and a sensor suite, including a capacitor voltage sensor, a capacitor current sensor, a battery voltage sensor, and/or a battery current sensor. The electrical system further includes a capacitor connected to the low-voltage power distribution bus and configured to provide a current source to the electrical system, along with a controller in communication with the sensor suite.

The controller in this construction is configured to measure one or more electrical parameters, including a system-level voltage, a system-level current, a battery voltage, and a battery current via the capacitor voltage sensor, the capacitor current sensor, the battery voltage sensor, and/or the battery current sensor, respectively. The controller is also configured to estimate, as a switching condition using the one or more electrical parameters, when a system load on the electrical system will cause a threshold excessive current inflow or outflow of the battery, the system load including a winch or a snow plow attachment. In response to the switching condition, the controller disconnects the battery from the electrical system by opening the switch, with the switching condition including a duration of a flow of the battery current into or out of the battery exceeding a calibrated threshold. The controller also connects the battery to the electrical system by closing the switch after a predetermined amount of time.

The above-described features and advantages and other possible features and advantages of the present disclosure will be apparent from the following detailed description of the best modes for carrying out the disclosure when taken in connection with the accompanying drawings.

### BRIEF DESCRIPTION OF THE DRAWINGS

FIG. 1 is a schematic illustration of a representative low-voltage electrical system and two exemplary motor vehicle usage scenarios in accordance with the disclosure.

FIG. 2A is a schematic circuit diagram illustrating an embodiment of the low-voltage electrical system depicted in FIG. 1.

FIG. 2B is a schematic circuit diagram illustrating an alternative embodiment of the low-voltage electrical system depicted in FIG. 2A.

FIG. 2C is a schematic circuit diagram illustrating an alternative embodiment of the low-voltage electrical system depicted in FIGS. 2A and 2B.

FIG. 3 illustrates a control circuit that may be used in the electrical system of FIGS. 1-2C.

FIG. 4 is a flow chart describing a method for controlling the low-voltage electrical system of FIGS. 1-3 according to a representative implementation.

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through the use of the accompanying drawings. Dimensions disclosed in the drawings or elsewhere herein are for the purpose of illustration.

### DETAILED DESCRIPTION

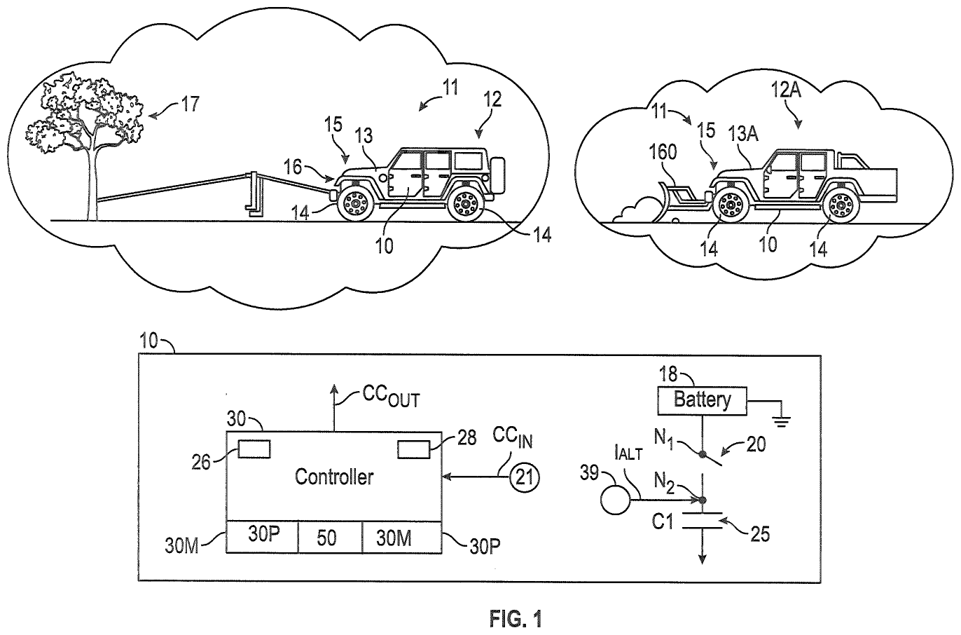

Referring to the drawings, wherein like reference numbers refer to like components, an electrical system 10 is illustrated in FIG. 1. The electrical system 10 may be used with a variety of possible host systems 11, including but not limited to motor vehicles and other mobile systems. For instance, a motor vehicle 12 having a vehicle body 13 and one or more powered road wheels 14 could act as the host system 11 for the electrical system 10. Such a motor vehicle 12 may be equipped with a high-load accessory 15, e.g., a winch 16 for use with a suitable anchor 17, e.g., a tree as shown, for leverage when using the winch 16. The accessory 15 could be alternatively constructed as a snow plow attachment 160, with the latter shown in the alternative motor vehicle 12A with its body 13A and a similar set of road wheels 14. Other possible embodiments of the accessory 15 may be used within the scope of the disclosure as high-load accessories or devices, the use of which triggers aspects of the control strategy described herein, and therefore the winch 16 and snow plow attachment 160 of FIG. 1 are non-limiting.

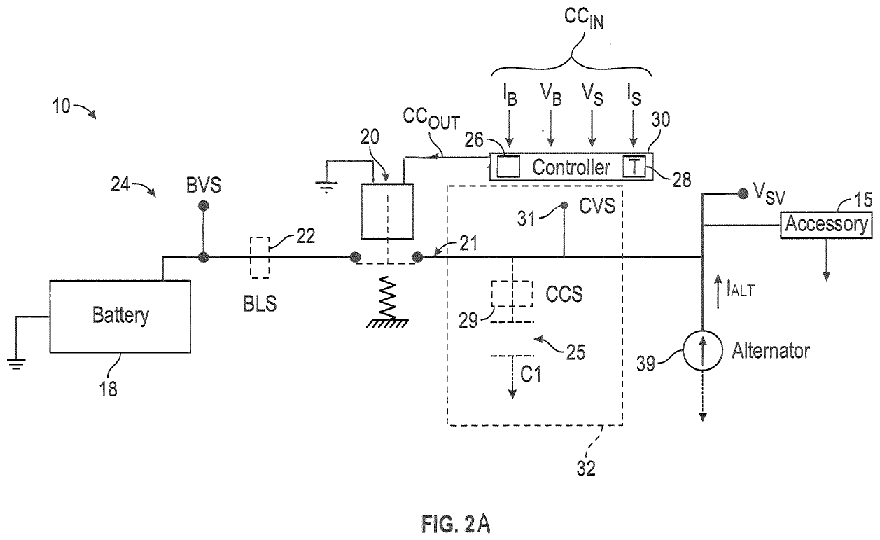

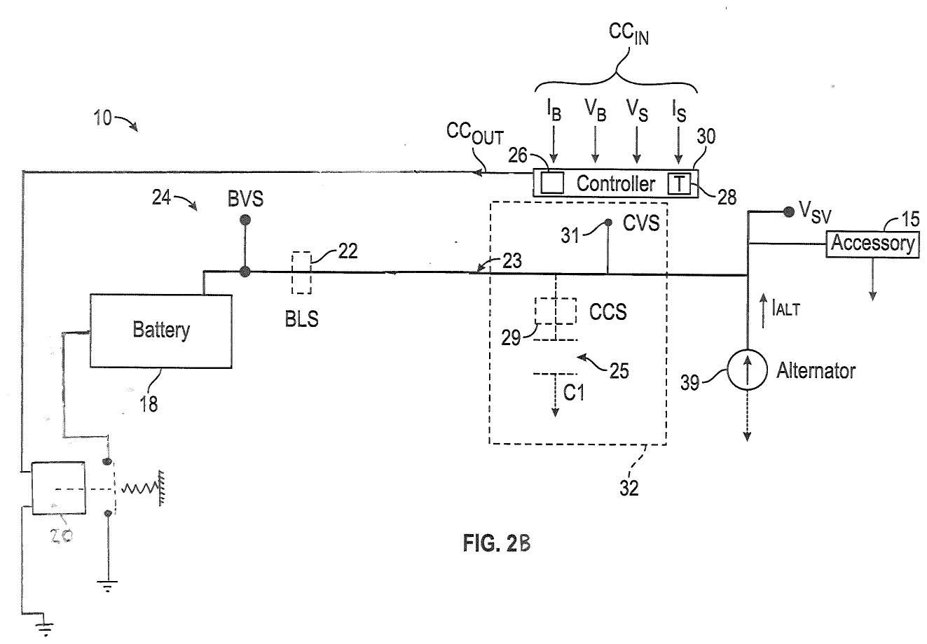

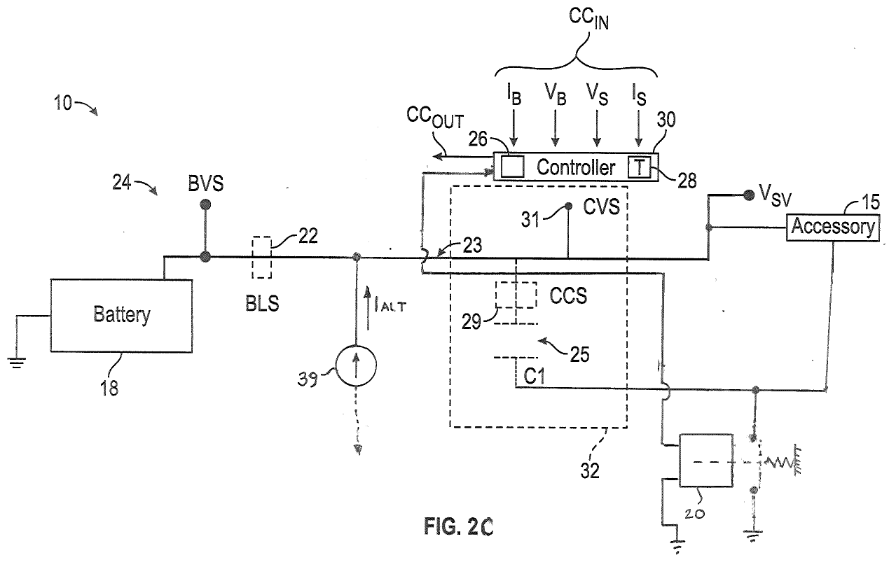

The electrical system 10 in the representative circuit topology of FIG. 1 includes a battery 18, e.g., a nominal 12-15 volt lead-acid battery. The battery 18 may include multiple batteries in other embodiments, and thus the battery 18 is described herein in the singular solely for illustrative simplicity. The electrical system 10 and the battery 18 are therefore considered herein to be “low-voltage”. The battery 18 is electrically connected to a switch 20, e.g., a contactor, solid-state switching device, relay, or the like. The switch 20 as shown in FIG. 2A is disposed on a low-voltage, high current-carrying power distribution bus 23, with the battery 18 being selectively connectable to the power distribution bus 23 via operation of the switch 20 as described below. FIGS. 2B and 2C depict alternative placement of the switch 20 in which on the ground side of the battery 18 (FIG. 2B) and on the ground side of the load and the capacitor (FIG. 2C), with the accessory 15 sharing the ground which becomes isolated when the switch 20 is open.

The electrical system 10 as contemplated herein includes one or more sensors in the form of a sensor suite 21. The sensor suite 21 is operable for measuring and outputting a set of input signals (CC_{IN}) to an electronic controller 30. Referring briefly to FIG. 2A, the sensor suite 21 could include a battery current sensor (BLS) 22, which is disposed between the battery 18 and the switch 20 and operable for measuring a battery current into or out of the battery 18, as described below with reference to FIGS. 2-4. A voltage capability/battery voltage of the battery 18 can be measured and reported via a battery voltage sensor (BVS) 24 in some embodiments. As part of the contemplated architecture, a capacitor (C1) 25 (also shown in FIG. 1) is connected to the power distribution bus 23. The switch 20 is used to selectively disconnect the battery 18 from the electrical system 10 during periods of high load demand, thereby protecting the battery 18 from damage due to deep power cycling. The capacitor 25 provides current into the power distribution bus 23 of FIG. 2A when an alternator 39 supplying an alternator current (I_{ALT}) is unable to meet the demands of the connected system load. At such times, the capacitor 25 provides or acts as an available current source to the electrical system 10, specifically when the battery 18 is disconnected.

The sensor suite 21 of FIG. 1 includes a minimum of one sensor, e.g., a Capacitor Voltage Sensor (CVS) 31 as shown in FIG. 2A (which measures a system-level voltage (VSV) as part of the present strategy), the Battery Current Sensor (BLS) 22, the Battery Voltage Sensor (BVS) 24, and/or a Capacitor Current Sensor (CCS) 29, with sensory outputs from such sensors of the sensor suite 21 embodying the input signals (CC_{IN}). The input signals (CC_{IN}) in turn are analyzed in real-time by the controller 30 to estimate conditions during which the capacity of battery 18 is sufficient, thus allowing the battery 18 to be connected to the power distribution bus 23 without excessive stress or damage to the battery 18 from excessive current flow through the switch 20. The controller 30 may include a timer (T) 28 that can be used by the controller 30 for decision making to manage hysteresis conditions, load cycle timing, time-based analysis of any of the sensor inputs to change the state of the switch 20, i.e., to either OPEN or CLOSED, to minimize damaging current into or out of the battery 18.

The electrical system 10 in the simplified embodiment of FIG. 1 may include one or more comparator circuits 26, which the controller 30 could use to monitor the system-level voltage and battery voltage. Each comparator circuit 26 can be used with the Capacitor Current Sensor 29, the Battery Load Sensor 22, the Battery Voltage Sensor 24, and/or the Capacitor Voltage Sensor 31, as appreciated by those skilled in the art. For example, using the comparator circuit(s) 26 the comparator circuit 26 could switch at a fixed or variable voltage that may be regulated by the controller 30. The controller 30 and the timer 28 may be integrated into a single microcontroller in one or more embodiments. The comparator circuit 26 or other suitable circuitry and logic is able to function as a threshold monitor in conjunction with the above-noted Capacitor Current Sensor 29, Battery Load Sensor 22, Battery Voltage Sensor 24, and/or Capacitor Voltage Sensor 31.

Collectively, the components of the representative electrical system 10 illustrated in FIGS. 1 and 2 estimate when loads on the motor vehicle 12 or 12A or other host system 11 will not cause an excessive current draw on the battery 18. When excessive current draw is detected, the battery 18 is automatically disconnected from the electrical system 10 via operation of the controller 30.

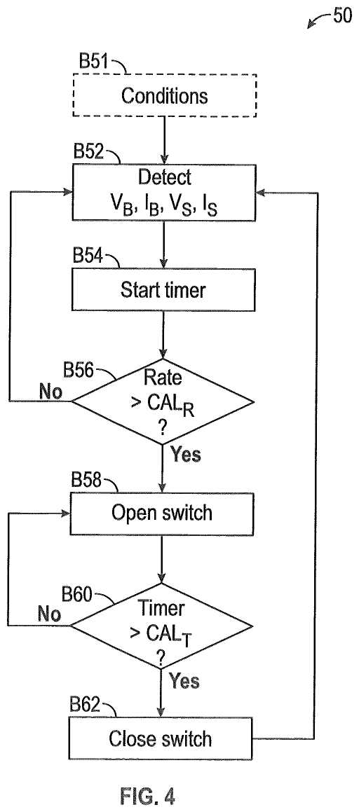

The term “controller” and related terms such as microcontroller, electronic control unit, etc., refer to one or various combinations of Application Specific Integrated Circuit(s) (ASIC), Field-Programmable Gate Array (FPGA), electronic circuit(s), central processing unit(s), e.g., microprocessor(s) 30P, and associated transitory and non-transitory memory/storage component(s) or memory 30M. The memory 30M includes tangible, non-transitory computer storage medium/media (read only, programmable read only, solid-state, random access, optical, magnetic, etc.). The memory 30M, on which computer-readable instructions embodying the method 50 of FIG. 4 may be recorded, is configured to store a machine-readable instruction set in the form of one or more software or firmware programs or routines, combinational logic circuit(s), input/output circuit(s) and devices, signal conditioning and buffer circuitry and other components that can be accessed by one or more processors to provide a described functionality.

Input/output circuit(s) and devices include analog/digital converters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and look-up tables. Each controller executes control routine(s) to provide desired functions. Ultimately, the controller 30 outputs electronic control output signals (arrow CC_{OUT}) to the switch 20 in the course of performing the method 50 of FIG. 4.

Still referring to FIG. 1, the battery 18 is selectively switched out of/disconnected from the low-voltage electrical system 10 by operation of the switch 20 when external loads on the motor vehicle 12 or 12A, exemplified as the high-load accessories 15, will cause excessive drain on the battery 18. ON/OFF state transition of the switch 20 can be coordinated via the controller 30 whenever the measured system-level voltage, i.e., the system-level/capacitor voltage (V_{S}) approaches the battery voltage (V_{B}). Among other attendant benefits, doing so minimizes current-related stress on the battery 18 when the switch 20 is initially opened or closed, and also reduces instances of electrical arcing and welding of the switch 20.

The controller 30 of FIG. 1 ultimately works in concert with the various sensors of the sensor suite 21 as described below to determine when the battery 18 is actively sourcing or receiving current above a predetermined maximum level or threshold. This threshold is tracked in real-time by the controller 30, e.g., using the timer 28, which enables the controller 30 to determine precisely when the battery 18 experiences a current inflow or outflow above the threshold for a statically or dynamically set duration. When this happens, the controller 30 commands the switch 20 to transition to an OPEN state, thus removing the battery 18 from the remainder of the electrical system 10. When the statically or dynamically set period of time elapses during which the switch 20 remains in the OPEN state, the controller 30 commands the switch 20 to transition to a CLOSED state. Closing the switch 20 reconnects the battery 18 to the electrical system 10, thus allowing the battery 18 to again experience a current inflow or outflow relative to any connected low-voltage components or devices as needed.

Referring now to FIG. 2A, the alternator 39 is connected to the low-voltage power distribution bus 23. In operation, the alternator 39 sources an electrical current (I_{ALT}) to the above-noted high-load accessory 15 during transient high-load periods, e.g., when using the representative winch 16 or snow plow attachment 160 of FIG. 1. In an area of the electrical system 10 referred to herein as the capacitor loop 32, the capacitor 25 is connected to the Capacitor Current Sensor (CLS) 29 and the Capacitor Voltage Sensor (CVS) 31. Thus, a system-level current (I_{C}) and the system-level/capacitor voltage (V_{S}) are measured and communicated to the controller 30 to detect onset of the high-load period. Proximate the battery 18, the above-noted Battery Voltage Sensor (BVS) 24 and the Battery Load Sensor (BLS) 22 are used to measure the battery voltage (V_{B}) and battery current (I_{B}), respectively. The measured battery voltage (V_{B}) and current (I_{B}) are then communicated to the controller 30 as part of the present approach, for instance over a controller area network (CAN) bus connection as appreciated in the art.

In the representative embodiment of FIG. 2A, the controller 30 can monitor current and/or voltage characteristics via the sensors 22, 24, 29, and 31. In some implementations, the controller 30 could perform an adaptive calibration sequence to monitor the battery current (I_{B}) through operation of the current sensor 22 while the accessory 15 is in use. The controller 30 uses the various measurements to determine a system-level voltage/capacitor voltage (V_{S}) and activates the switch 20 when the system-level voltage reaches a predetermined/calibrated or dynamically set voltage limit at a calibrated or adaptive rate. Timing of the opening or closing of the switch 20 can be coordinated by the controller 30, which would help optimize the system-level/capacitor voltage (V_{S}) when the high-load accessory 15 is in use. As noted above, the switch 20 may be placed elsewhere in the circuit, with FIGS. 2B and 2C illustrating two possibilities within the scope of the disclosure.

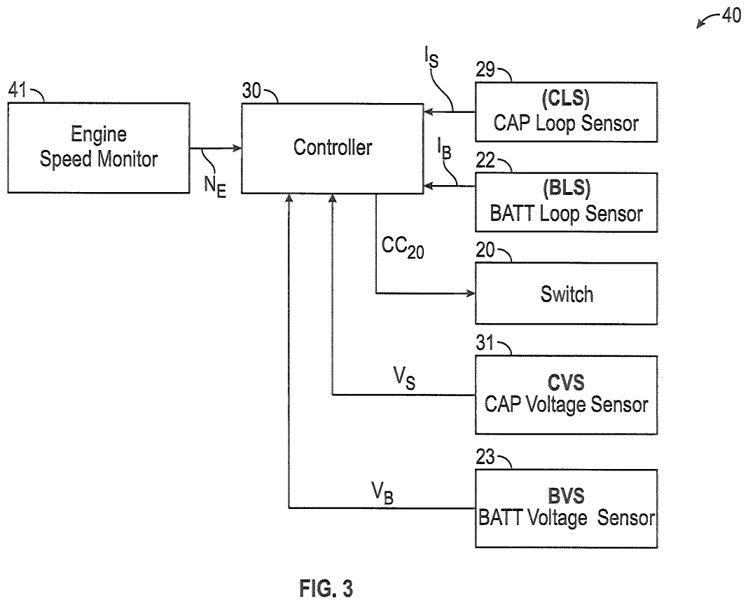

Referring now to FIG. 3, the representative motor vehicles 12 and 12A of FIG. 1 could be engine-driven in a possible construction. That is, the motor vehicles 12 and 12A could include an internal combustion engine or a diesel engine (not shown) connected to the road wheels 14 as a source of propulsion torque. In such a case, engine speed could be monitored and reported as an electronic engine speed signal (N_{E}) to the controller 30 by an engine speed monitor 41, e.g., a digital control unit or processor of the motor vehicle 12 or 12A, to determine if the motor vehicle 12, 12A is running. When the motor vehicle 12, 12A (i.e., its engine) is not actively fueled and running, the switch 20 may be commanded by the controller 30 to close, thereby connecting the battery 18 to the electrical system 10A. In this engine-off mode, the battery 18 can provide power to connected low-voltage devices as needed.

As illustrated schematically in FIG. 3, the controller 30 in such an embodiment is in communication with the switch 20. The controller 30 is configured to change the OPEN/CLOSED state of the switch 20 via the electronic output control signals (CC_{OUT}), e.g., a voltage signal that triggers operation of the switch 20 in a configuration-specific manner. The switch 20 could be normally closed in a possible non-limiting embodiment, such that the default closed state of the switch 20 ensures that the battery 18 remains connected to the electrical system 10 absent the electronic output control signal (CC_{OUT}). For proper coordination of the switch 20, the controller 30 remains in communication with the various sensors BLS 22, BVS 24, CCS 29, and CVS 31 as described above.

Referring to FIG. 4, a method 50 is illustrated in a series of logical process steps or blocks. Each block represents a particular action to be performed by the controller 30 of FIGS. 1-3 in conjunction with the associated hardware of the electrical system 10. Method 50 is described for an embodiment in which the host system 11 of FIG. 1 is one of the motor vehicle 12 or 12A. Those skilled in the art will recognize that other embodiments of the host system 11 could implement the method 50 within the scope of the disclosure, and therefore the method 50 is not limited to vehicular uses.

Beginning with block B51 (“Conditions”), the method 50 may be performed at predetermined times, for instance based on the measured or reported engine speed indicated by the electronic engine speed signal (N_{E}) of FIG. 3. When the motor vehicle 12, 12A is not running, the battery 18 remains electrically connected to the electrical system 10 as noted above. The method 50 proceeds to block B52 when the conditions of block B51 have been satisfied.

Block B52 includes measuring an electrical parameter of the electrical system 10 of FIGS. 1 and 2 on the power distribution bus 23 thereof via a sensor 22, 24, 29, and/or 31. For example, block B52 could entail measuring a current or a voltage at one or more nodes of the electrical system 10 as described above. The controller 30 thus receives the measured battery current and voltage (I_{B} and V_{B}) from the battery current sensor 22 and the battery voltage sensor 24 at a particular sampling interval, and the measured system-level current and system-level voltage (I_{S} and V_{SIC}) from the Capacitor Current Sensor 29 and the Capacitor Voltage Sensor 31, respectively. The method 50 proceeds to block B54 once these electrical values have been measured and reported.

At block B54, the controller 30 initiates the timer 28 shown in FIGS. 1 and 2A-C. The method 50 proceeds to block B56 as the timer 28 continues to run.

At block B56, the controller 30 estimates, as a switching condition using the electrical parameter(s) measured in block B52, when a system load on the electrical system 10 will cause a threshold excessive current condition, i.e., a current inflow to or outflow from the battery 18. For instance, block B56 could include determining a duration of a flow of the battery current (I_{B}) into/out of the battery 18 via the timer 28, and in response to the duration, opening the switch 20 to disconnect the battery 18 from the low-voltage electrical system 10, 10A.

As part of block B56, the controller 30 could determine if a rate of change of the measured battery current (I_{B}) and/or the measured battery voltage (V_{B}) indicates excessive current of the battery 18. The controller 30 may be programmed with a calibrated threshold rate (CAL_{R}) indicative of such excessive current, which may vary based on the application and construction of the host system 11. The method 50 proceeds to block B58 when the rate of change of the measured battery current (I_{B}) and/or battery voltage (V_{B}) exceeds the calibrated threshold rate (CAL_{R}). The method 50 returns to block B52 when the rate remains below the threshold rate (CAL_{R}).

Block B58 of FIG. 4 includes disconnecting the battery 18 from the electrical system 10 in response to the above-noted switching condition. Block B58 may include opening the switch 20 of FIGS. 1 and 2. To this end, the controller 30 could transmit the electronic output control signals (CC_{OUT}) of FIGS. 1-3 to the switch 20 to cause the switch 20 to transition to an OPEN state. If the switch 20 is a normally-open type, the electronic output control signals (CC_{OUT}) would hold the switch 20 closed. In such an embodiment, block B58 could entail discontinuing the electronic output control signals (CC_{OUT}). In either approach, the method 50 proceeds to block B60 after the switch 20 has opened and the battery 18 has been electrically disconnected from the electrical system 10.

At block B60, the method 50 includes comparing the present value of the timer 28 of FIGS. 1 and 2 to a calibrated time limit (CAL_{T}) via the controller 30. The method 50 proceeds to block B62 when the timer 28 reaches the calibrated time limit (CAL_{T}), i.e., a predetermined period of time such as 1-2 seconds or another application-suitable duration. That is, the controller 40 may determine when the switch 20 has been in the OPEN state for a predetermined period of time, with the controller 30 thereafter closing the switch 20 to thereby reconnect the battery 18 to the electrical system 10 when the switch 20 has been in the OPEN state for the predetermined period of time. Blocks B58 and B60 are performed in a loop until the timer 28 reaches the calibrated time limit (CAL_{T}). The specific value used for implementing the calibrated time limit (CAL_{T}) can vary with the particular application and configuration of the low-voltage electrical system 10, 10A, with exemplary durations of about 1-5 seconds being possible in one or more embodiments.

Block B62 includes commanding the switch 20 to transition to a CLOSED state. As with block B58, this action entails transmitting the electronic output control signals (CC_{OUT}) to the switch 20 to cause the switch 20 to change its present state from OPEN to CLOSED. Closing of the switch 20 thus reconnects the battery 18 to the power distribution bus 23 of FIG. 2A.

As will be appreciated by those skilled in the art with the benefit of the present disclosure, the controller 30 and its programmed method 50 enable selective switching of the battery 18 into and out of the electrical system 10 as needed based on the presented system loads causing a damaging amount of current to flow into our out of the battery 18. To that end, the controller 30 is configured to determine, via the timer, when a voltage level of the low-voltage power distribution bus 23 is below a nominally-expected battery voltage for a first period of time, and to switch the battery 18 out of the electrical system 10 until the voltage level rises above the nominally-expected battery voltage for a second period of time.

Among other attendant benefits, the disclosed solutions help prevent degradation of and damage to the battery 18 by removing it from the electrical system 10, thereby shielding the battery 18 from large current fluctuations. The battery 18 remains connected to the electrical system 10 at other times, specifically when the controller 30 estimates that the loads will not cause excessive drain. These and other benefits of the present teachings will be appreciated by those skilled in the art in view of the foregoing disclosure.

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present disclosure.

Furthermore, the embodiments shown in the drawings or the characteristics of various embodiments mentioned in the present description are not necessarily to be understood as embodiments independent of each other. Rather, it is possible that each of the characteristics described in one of the examples of an embodiment can be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method for use aboard a host system having an electrical system, the electrical system including a battery and a power distribution bus, the method comprising:
measuring at least one electrical parameter on the power distribution bus, via a sensor suite, the electrical parameter including a current and/or a voltage on at least one node of the electrical system;
estimating, via a controller as a switching condition using the electrical parameter, when a system load on the electrical system will cause a threshold excessive current condition of the battery; and
in response to the switching condition, disconnecting the battery from the electrical system via the controller by opening a switch of the electrical system.

2. The method of claim 1, wherein measuring the at least one electrical parameter includes measuring the current via a current sensor as a battery current of the battery, and/or measuring the voltage via a voltage sensor as a battery voltage of the battery.

3. The method of claim 1, wherein the electrical system includes a capacitor that is connected to the power distribution bus, further comprising:
providing an available current source to the electrical system via the capacitor when the battery is disconnected from the electrical system.

4. The method of claim 1, wherein measuring the at least one electrical parameter includes measuring the current as a battery current of the battery, further comprising:
determining a duration of a flow of the battery current into or out of the battery via a timer; and
in response to the duration, opening the switch to disconnect the battery from the electrical system.

5. The method of claim 1, further comprising:
determining when the switch has been in an open state for a predetermined period of time; and
closing the switch to thereby reconnect the battery to the electrical system when the switch has been in the open state for the predetermined period of time.

6. The method of claim 1, wherein the host system is a motor vehicle, further comprising:
determining if the motor vehicle is not running; and
closing the switch when the motor vehicle is not running to thereby connect the battery to the electrical system.

7. The method of claim 6, wherein the motor vehicle includes an engine connected to one or more road wheels, and wherein determining if the motor vehicle is not running includes processing an engine speed signal via the controller.

8. The method of claim 7, wherein the system load includes a winch or a snow plow attachment.

9. The method of claim 1, wherein the electrical system includes one or more comparator circuits, and wherein estimating when the system load on the electrical system will cause the threshold excessive current of the battery is performed by the controller using the one or more comparator circuits.

10. An electrical system for a host system, comprising:
a low-voltage power distribution bus;
a switch disposed on the low-voltage power distribution bus;
a battery that is selectively connectable to the low-voltage power distribution bus via the switch;
a timer;
a sensor suite having one or more sensors;
a capacitor connected the low-voltage power distribution bus; and
a controller in communication with the sensor suite, wherein the controller is configured to:
determine an electrical parameter of the battery via the sensor suite, the electrical parameter including at least one of a battery current or a battery voltage of the battery;
estimate, as a switching condition using the electrical parameter and the timer, when a system load on the electrical system will cause a threshold excessive current outflow or inflow of the battery; and
in response to the switching condition, disconnect the battery from the electrical system by opening the switch without disconnecting the capacitor from the low-voltage power distribution bus.

11. The electrical system of claim 10, wherein the sensor suite includes a current sensor and/or a voltage sensor, and wherein the controller is configured to determine the electrical parameter by measuring the battery current via the current sensor and/or the battery voltage via the voltage sensor.

12. The electrical system of claim 10, wherein the capacitor is connected to the switch and configured to provide a current source to the electrical system when the battery is disconnected from the electrical system.

13. The electrical system of claim 10, further comprising:
a timer, wherein the electrical parameter includes the battery current, and wherein the controller is configured to:
determine a duration of the current outflow or inflow of the battery using the timer; and
disconnect the battery from the electrical system in response to the duration.

14. The electrical system of claim 13, wherein the controller is configured to:
determine, via the timer, when a voltage level of the low-voltage power distribution bus is below a nominally-expected battery voltage for a first period of time; and
disconnect the battery from the electrical system until the voltage level of the electrical system rises above the nominally-expected battery voltage for a second period of time.

15. The electrical system of claim 10, wherein the controller is further configured to:
determine when the switch has been in an open state for a predetermined period of time; and
reconnect the battery to the electrical system when the switch has been in the open state for the predetermined period of time.

16. The electrical system of claim 10, wherein the host system is a motor vehicle, and wherein the controller is configured to:
determine if the motor vehicle is not running; and
close the switch when the motor vehicle is not running to thereby connect the battery to the electrical system.

17. The electrical system of claim 16, wherein the motor vehicle includes an engine connected to one or more road wheels, the controller is in communication with an engine speed monitor of the motor vehicle, and the controller is configured to determine if the motor vehicle is not running using an engine speed signal.

18. The electrical system of claim 16, further comprising:
the system load, wherein the system load includes a winch or a snow plow attachment.

19. An electrical system for a motor vehicle having an engine, comprising:
a low-voltage power distribution bus;
a switch disposed on the low-voltage power distribution bus;
a battery that is selectively connectable to the low-voltage power distribution bus via the switch;
a sensor suite, including a capacitor voltage sensor, a capacitor current sensor, a battery voltage sensor, and/or a battery current sensor;
a capacitor connected to the low-voltage power distribution bus and configured to provide a current source to the electrical system; and
a controller in communication with the sensor suite, wherein the controller is configured to:
measure one or more electrical parameters, including a system-level voltage, a system-level current, a battery voltage, and a battery current via the capacitor voltage sensor, the capacitor current sensor, the battery voltage sensor, and/or the battery current sensor, respectively;
estimate, as a switching condition using the one or more electrical parameters, when a system load on the electrical system will cause a threshold excessive current inflow or outflow of the battery, the system load including a winch or a snow plow attachment;
in response to the switching condition, disconnect the battery from the electrical system by opening the switch, the switching condition including a duration of a flow of the battery current into or out of the battery exceeding a calibrated threshold; and
connect the battery to the electrical system by closing the switch after a predetermined amount of time.

20. The electrical system of claim 19, wherein the controller is configured to:
receive an engine speed signal indicative of a speed of the engine;
determine if the motor vehicle is not running using the engine speed signal; and
connect the battery to the electrical system when the motor vehicle is not running by closing the switch.
